(19) United States
(12) Patent Application Publication
(10) Pub. No.: US 2017/0315871 A1
(43) Pub. Date: Nov. 2, 2017

(54) RETRYING WRITE OPERATIONS AFTER FAILURES

(71) Applicant: International Business Machines Corporation, Armonk, NY (US)

(72) Inventors: S. Christopher Gladwin, Chicago, IL (US); Asimuddin Kazi, Naperville, IL (US)

(21) Appl. No.: 15/651,161

(22) Filed: Jul. 17, 2017

Related U.S. Application Data
(63) Continuation-in-part of application No. 14/315,925, filed on Jun. 26, 2014.
(60) Provisional application No. 61/871,649, filed on Aug. 29, 2013.

(51) Int. Cl. G06F 11/14; G06F 17/30; G11C 29/44; G06F 11/08

(52) U.S. Cl. CPC G06F 11/1402; G11C 29/44; G06F 17/30091; G06F 11/08

(57) ABSTRACT

A computing device includes interfaces and communicates with a dispersed storage network (DSN) and issues write slice requests to a set of storage units (SUs) to store distributedly a set of encoded data slices (EDSs) associated with a data object. When at least a write threshold number of favorable write slice responses are received, the computing device identifies an EDS without write confirmation and an SU associated therewith. The computing device stores the EDS without write confirmation in a slice cache memory and, based on a determination to reissue a write slice request associated with the EDS without write confirmation, the computing device reissues the write slice request. When a favorable write slice response is received from the SU associated with the EDS without write confirmation, the computing device deletes the EDS of the at least the write threshold number of EDSs without write confirmation from the slice cache memory.

### CROSS REFERENCE TO RELATED PATENTS

The present U.S. Utility patent application claims priority pursuant to 35 U.S.C. §120, as a continuation-in-part (CIP) of U.S. Utility patent application Ser. No. 14/315,925, entitled “DISPERSED STORAGE BASED ON ESTIMATED LIFE AND METHODS FOR USE THEREWITH,” filed Jun. 26, 2014, which claims priority pursuant to 35 U.S.C. §119(e) to U.S. Provisional Application No. 61/871,649, entitled “OPTIMIZING DATA STORAGE IN A DISPERSED STORAGE NETWORK,” filed Aug. 29, 2013, both of which are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersing error encoded data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

Prior art data storage systems do not provide acceptable solutions to ensure that data is properly and effectively stored therein. In addition, there may be instances when data fails to be stored, and the prior art data storage systems do not provide acceptable solutions to ensure a high level of performance and confidences to users of the prior art data storage systems.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIG. 9 is a schematic block diagram of another embodiment of a dispersed or distributed storage network (DSN) in accordance with the present invention;

FIG. 10A is a flowchart illustrating an example of completing writing of encoded data slices in accordance with the present invention; and

FIG. 10B is a diagram illustrating an embodiment of a method 1002 for execution by one or more computing devices in accordance with the present invention.

### DETAILED DESCRIPTION OF THE INVENTION

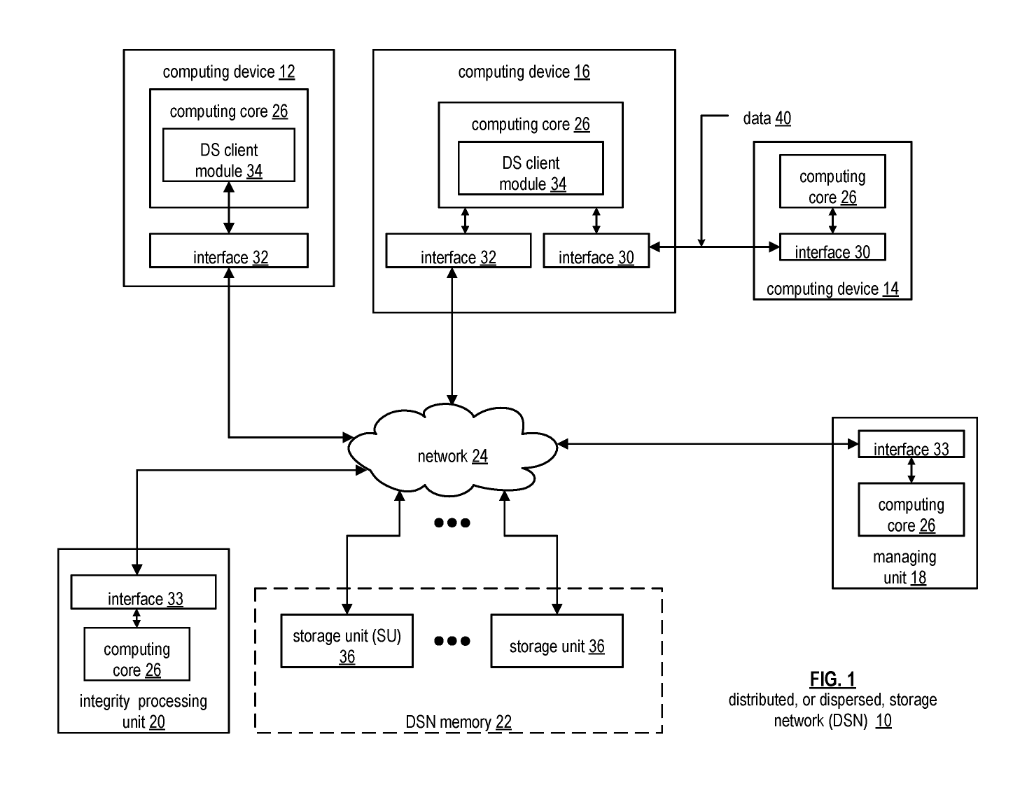

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

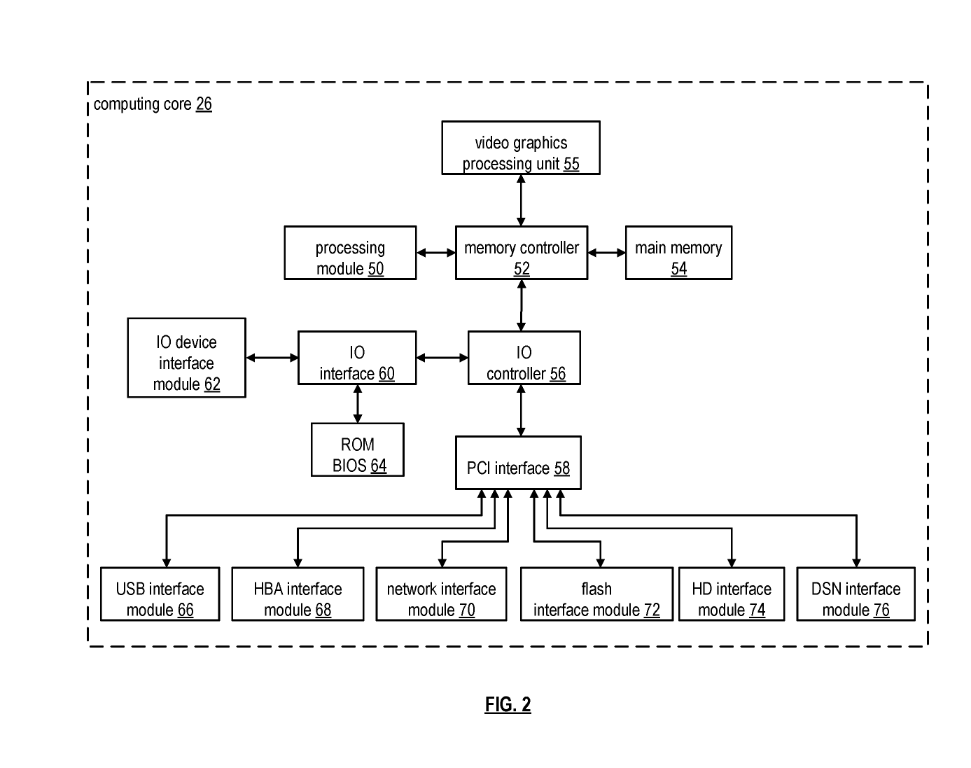

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 & 16 and the DSN memory 22. As yet another example, interface 33 supports a communication link for each of the managing unit 18 and the integrity processing unit 20 to the network 24.

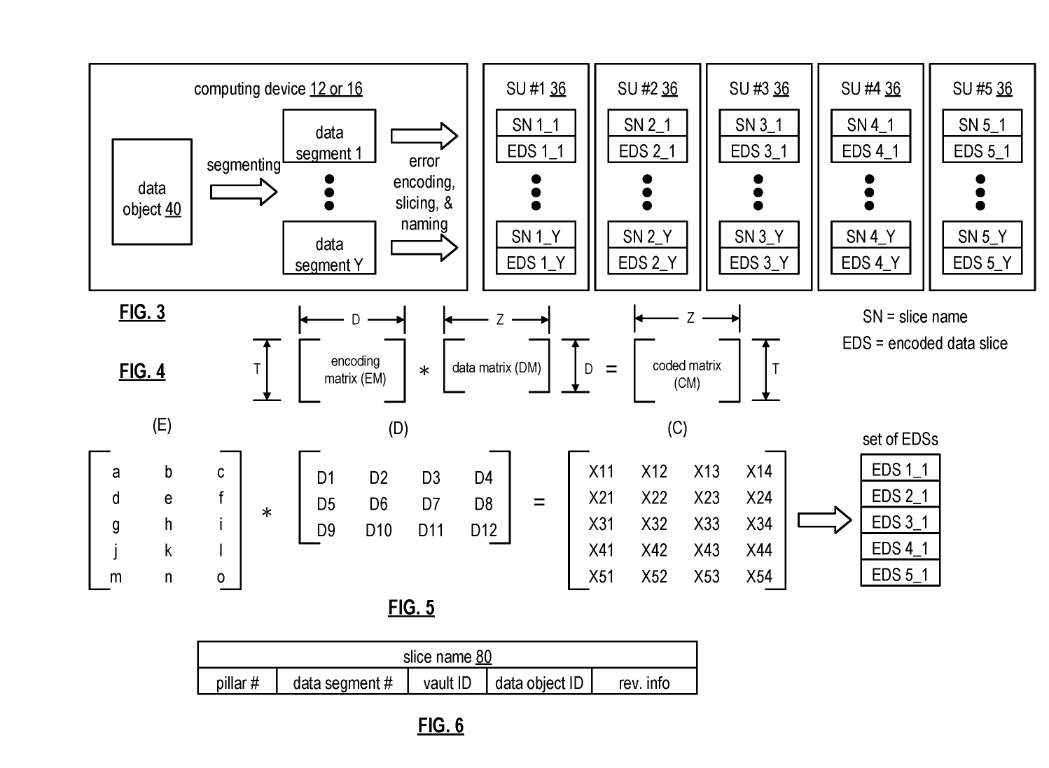

Computing devices 12 and 16 include a dispersed storage (DS) client module 34, which enables the computing device to dispersed storage error encode and decode data as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The DSN managing unit 18 creates and stores user profile information (e.g., an access control list (ACL)) in local memory and/or within memory of the DSN module 22. The user profile information includes authentication information, permissions, and/or the security parameters. The security parameters may include encryption/decryption scheme, one or more encryption keys, key generation scheme, and/or data encoding/decoding scheme.

The DSN managing unit 18 creates billing information for a particular user, a user group, a vault access, public vault access, etc. For instance, the DSN managing unit 18 tracks the number of times a user accesses a non-public vault and/or public vaults, which can be used to generate a per-access billing information. In another instance, the DSN managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

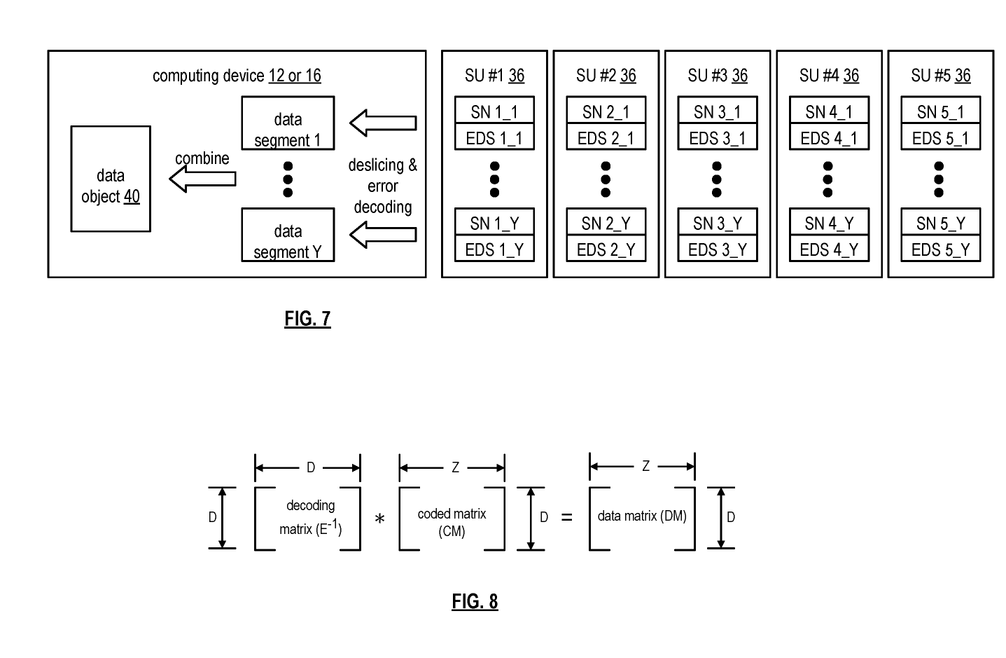

Returning to the discussion of FIG. 3, the computing device also creates a slice name (SN) for each encoded data slice (EDS) in the set of encoded data slices. A typical format for a slice name 60 is shown in FIG. 6. As shown, the slice name (SN) 60 includes a pillar number of the encoded data slice (e.g., one of 1-T), a data segment number (e.g., one of 1-Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

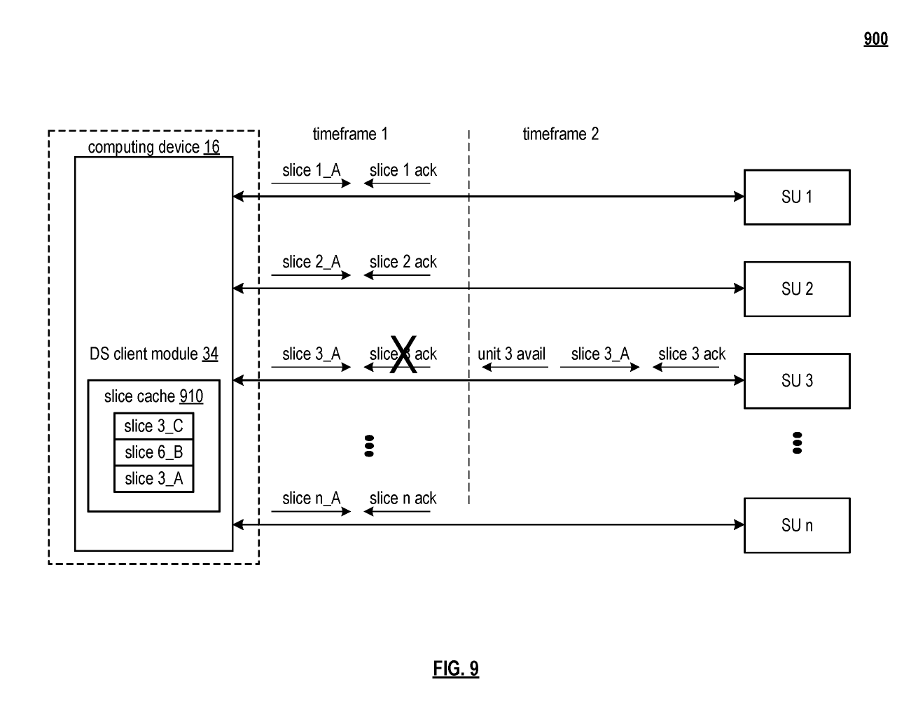

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

In some examples, note that dispersed or distributed storage network (DSN) memory includes one or more of a plurality of storage units (SUs) such as SUs 36 (e.g., that may alternatively be referred to a distributed storage and/or task network (DSTN) module that includes a plurality of distributed storage and/or task (DST) execution units 36 that may be located at geographically different sites (e.g., one in Chicago, one in Milwaukee, etc.). Each of the SUs (e.g., alternatively referred to as DST execution units in some examples) is operable to store dispersed error encoded data and/or to execute, in a distributed manner, one or more tasks on data. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, etc.

FIG. 9 is a schematic block diagram 900 of another embodiment of a dispersed or distributed storage network (DSN) in accordance with the present invention. This diagram includes a schematic block diagram of another embodiment of a dispersed storage network that includes the DS client module 34 (e.g., of a computing device from FIG. 1 such as computing device 16) and a set of SUs 1-n of FIG. 1. The DS client module 34 includes a slice cache memory 910. The system functions to store sets of encoded data slices in the set of SUs 1-n. In an example of operation, in a first timeframe, the DS client module 34 issues a set of write slice requests 1-n to store a set of encoded data slices A in the set of SUs 1-n. When receiving at least a write threshold number of favorable write slice responses (e.g., acknowledging storage of an associated read threshold number of encoded data slices of the set of encoded data slices), the DS client module 34 identifies any encoded data slices not associated with a storage acknowledgment. For instance, the DS client module 34 does not receive a write slice response for encoded data slice 3.

The DS client module 34 stores the encoded data slices not associated with the storage acknowledgment (e.g., without write confirmation) in the slice cache memory 910. For example, the DS client module 34 stores encoded data slice 3_A in a slice cache memory 910. The DS client module 34 overwrites an oldest previously stored encoded data slice in the slice cache memory 910 when the slice cache memory 910 is full. The DS client module 34 determines whether to resend an encoded data slice without write confirmation to associated SU based on one or more of receiving a SU availability indicator, interpreting a resend schedule, receiving an error message, receiving an access request response, receiving a resend request that request resending encoded data slices without write confirmation, and receiving a rebuilding request. For example, the DS client module 34 determines to resend encoded data slice 3_A when SU 3 issues a SU 3 available message.

When determining to resend the encoded data slice without write confirmation, the DS client module 34 resends the encoded data slice without write confirmation to the associated SU. For example, the DS client module 34 resends encoded data slice 3_A to the SU 3. When receiving a favorable write slice response, the DS client module 34 deletes the encoded data slice without write confirmation from the slice cache memory 910. For example, the DS client module 34 receives an encoded data slice 3 write slice response (e.g., a favorable acknowledgment) and deletes encoded data slice 3_A from the slice cache memory 910.

In an example of operation and implementation, a computing device that includes the DS client module 34 is implemented to include an interface configured to interface and communicate with a dispersed or distributed storage network (DSN), a memory that stores operational instructions, and a processing module operably coupled to the interface and to the memory, wherein the processing module, when operable within the computing device based on the operational instructions, is configured to perform various operations and functions.

In some examples, the computing device is configured to issue a plurality of write slice requests to a set of storage units (SUs) to store distributedly a set of encoded data slices (EDSs) associated with a data object. Note that such a data object is segmented into a plurality of data segments, and a data segment of the plurality of data segments is dispersed error encoded in accordance with dispersed error encoding parameters to produce the set of EDSs. Also, note that a write threshold number of EDSs provides for a successful transfer of the set of EDSs from a first at least one location in the DSN to a second at least one location in the DSN.

Also, when at least a write threshold number of favorable write slice responses are received from at least the write threshold number of SUs of the set of SUs acknowledging storage of at least the write threshold number of EDSs of the set of EDSs, the computing device is configured to identify an EDS of the at least the write threshold number of EDSs without write confirmation and an SU associated with the EDS of the at least the write threshold number of EDSs without write confirmation.

The computing device is also configured to store the EDS of the at least the write threshold number of EDSs without write confirmation in a slice cache memory of the computing device. then, based on a determination to reissue a write slice request of the plurality of write slice requests associated with the EDS of the at least the write threshold number of EDSs without write confirmation, the computing device is configured to reissue the write slice request of the plurality of write slice requests to the SU associated with the EDS of the at least the write threshold number of EDSs without write confirmation.

When a favorable write slice response is received from the SU associated with the EDS of the at least the write threshold number of EDSs without write confirmation in response to the write slice request of the plurality of write slice requests, the computing device is configured to delete the EDS of the at least the write threshold number of EDSs without write confirmation from the slice cache memory of the computing device.

In some alternative examples, when an unfavorable write slice response is received from the SU of the plurality of SUs associated with the EDS of the at least the write threshold number of EDSs without write confirmation in response to the write slice request of the plurality of write slice requests and based on another determination to reissue another write slice request of the plurality of write slice requests associated with the EDS of the at least the write threshold number of EDSs without write confirmation, the computing device is configured to reissue the another write slice request of the plurality of write slice requests to the SU of the plurality of SUs associated with the EDS of the at least the write threshold number of EDSs without write confirmation.

In even other examples, the computing device is configured to delete the EDS of the at least the write threshold number of EDSs without write confirmation from the slice cache memory of the computing device and store a new EDS of the at least the write threshold number of EDSs without write confirmation in the slice cache memory of the computing device when available storage space of the slice cache memory of the computing device is below a threshold.

In yet other examples, the computing device is configured to determine whether to reissue the write slice request of the plurality of write slice requests associated with the EDS of the at least the write threshold number of EDSs without write confirmation based on at least one of receiving a SU availability indicator, interpreting a resend schedule, receiving an error message, receiving an access request response, receiving a resend request that request resending EDSs without write confirmation, or receiving a rebuilding request.

In some examples, note that a decode threshold number of EDSs are needed to recover the data segment, and a read threshold number of EDSs provides for reconstruction of the data segment. The set of EDSs is of pillar width and includes a pillar number of EDSs, and each of the decode threshold, the read threshold, and the write threshold is less than the pillar number. Also, in some examples, the write threshold number is greater than or equal to the read threshold number that is greater than or equal to the decode threshold number.

Note that the computing device may be located at a first premises that is remotely located from at least one SU of a plurality of SUs within the DSN. Also, note that the computing device may be of any of a variety of types of devices as described herein and/or their equivalents including a SU of any group and/or set of SUs within the DSN, a wireless smart phone, a laptop, a tablet, a personal computers (PC), a work station, and/or a video game device. Note also that the DSN may be implemented to include or be based on any of a number of different types of communication systems including a wireless communication system, a wire lined communication systems, a non-public intranet system, a public internet system, a local area network (LAN), and/or a wide area network (WAN).

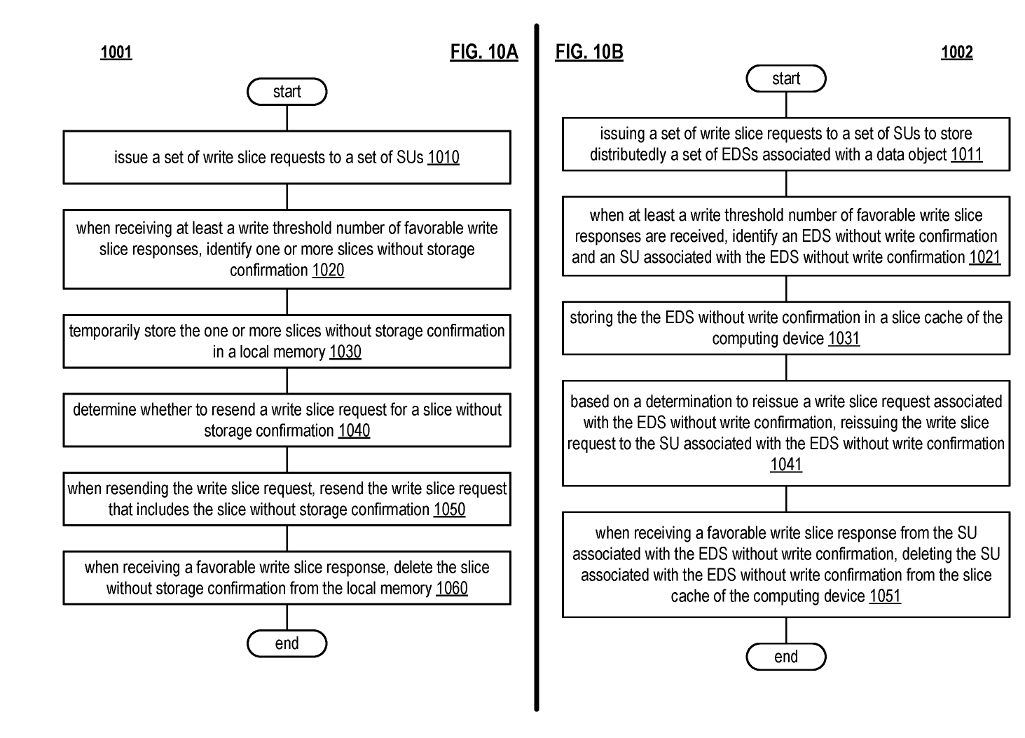

FIG. 10A is a flowchart illustrating an example of completing writing of encoded data slices in accordance with the present invention. This diagram includes a flowchart illustrating an example of completing writing of encoded data slices. Method 1001 begins at a step 1010 where a processing module (e.g., of a distributed storage (DS) client module) issues a set of write slice requests to a set of storage units. The issuing includes generating and sending at least a write threshold number of write slice requests, where each request includes an encoded data slice. When receiving at least a write threshold number of favorable write slice responses, the method 1001 continues at the step 1020 where the processing module identifies one or more encoded data slices without storage confirmation. The identifying includes receiving write slice responses, determining whether each write slice response indicates favorable writing, and detecting whether no write slice response has been received for an encoded data slice within a response timeframe.

The method 1001 continues at the step 1030 where the processing module temporarily stores the one or more encoded data slices without storage confirmation in a local memory (e.g., a cache memory and/or a slice cache memory such as slice cache memory 910). The storing includes overwriting an oldest encoded data slice previously stored in the local memory when the local memory is full. The method 1001 continues at the step 1040 where the processing module determines to resend a write slice request for an encoded data slice without storage confirmation. The determining includes at least one of receiving an availability indicator, interpreting a resend schedule, receiving an error message, receiving an access request response, receiving a resend request, and receiving a rebuilding request.

When resending the write slice request, the method 1001 continues at the step 1050 where the processing module resends the write slice request that includes the encoded data slice without storage confirmation. For example, the processing module retrieves the encoded data slice without storage confirmation from the local memory and outputs the encoded data slice to an associated storage unit. When receiving a favorable write slice response, the method 1001 continues at the step 1060 where the processing module deletes the encoded data slice without storage confirmation from the local memory. The deleting includes receiving a write slice response and detecting favorable writing within a response timeframe from the resending of a write slice request.

FIG. 10B is a diagram illustrating an embodiment of a method 1002 for execution by one or more computing devices in accordance with the present invention. The method 1002 operates in step 1011 by issuing (e.g., via an interface of the computing device that is configured to interface and communicate with a dispersed or distributed storage network (DSN)) a plurality of write slice requests to a set of storage units (SUs) to store distributedly a set of encoded data slices (EDSs) associated with a data object. Note that such a data object is segmented into a plurality of data segments, and a data segment of the plurality of data segments is dispersed error encoded in accordance with dispersed error encoding parameters to produce the set of EDSs. Also, a write threshold number of EDSs provides for a successful transfer of the set of EDSs from a first at least one location in the DSN to a second at least one location in the DSN.

When at least a write threshold number of favorable write slice responses are received via the interface from at least the write threshold number of SUs of the set of SUs acknowledging storage of at least the write threshold number of EDSs of the set of EDSs, the method 1002 continues in step 1021 by identify an EDS of the at least the write threshold number of EDSs without write confirmation and an SU associated with the EDS of the at least the write threshold number of EDSs without write confirmation.

The method 1002 then operates in step 1031 by storing the EDS of the at least the write threshold number of EDSs without write confirmation in a slice cache memory of the computing device. Then, based on a determination to reissue a write slice request of the plurality of write slice requests associated with the EDS of the at least the write threshold number of EDSs without write confirmation, the method 1002 continues in step 1041 by reissuing via the interface the write slice request of the plurality of write slice requests to the SU associated with the EDS of the at least the write threshold number of EDSs without write confirmation.

When a favorable write slice response is received from the SU associated with the EDS of the at least the write threshold number of EDSs without write confirmation in response to the write slice request of the plurality of write slice requests, the method 1002 then operates in step 1031 by deleting the EDS of the at least the write threshold number of EDSs without write confirmation from the slice cache memory of the computing device.

In some examples, when an unfavorable write slice response is received from the SU of the plurality of SUs associated with the EDS of the at least the write threshold number of EDSs without write confirmation in response to the write slice request of the plurality of write slice requests and based on another determination to reissue another write slice request of the plurality of write slice requests associated with the EDS of the at least the write threshold number of EDSs without write confirmation, the method 1002 alternatively operates by reissuing via the interface the another write slice request of the plurality of write slice requests to the SU of the plurality of SUs associated with the EDS of the at least the write threshold number of EDSs without write confirmation.

In even other examples, the method 1002 alternatively operates by deleting the EDS of the at least the write threshold number of EDSs without write confirmation from the slice cache memory of the computing device and store a new EDS of the at least the write threshold number of EDSs without write confirmation in the slice cache memory of the computing device when available storage space of the slice cache memory of the computing device is below a threshold.

In yet other examples, the method 1002 alternatively operates by determining whether to reissue the write slice request of the plurality of write slice requests associated with the EDS of the at least the write threshold number of EDSs without write confirmation based on at least one of receiving a SU availability indicator, interpreting a resend schedule, receiving an error message, receiving an access request response, receiving a resend request that request resending EDSs without write confirmation, or receiving a rebuilding request.

In some examples, note that a decode threshold number of EDSs are needed to recover the data segment, and a read threshold number of EDSs provides for reconstruction of the data segment. The set of EDSs is of pillar width and includes a pillar number of EDSs, and each of the decode threshold, the read threshold, and the write threshold is less than the pillar number. Also, in some examples, the write threshold number is greater than or equal to the read threshold number that is greater than or equal to the decode threshold number.

Note that such a computing device performing the method 1002 may be implemented and located at a first premises that is remotely located from at least one SU of the plurality of SUs within the DSN. Also, note that such a DSN may include a wireless communication system, a wire lined communication systems, a non-public intranet system, a public internet system, a local area network (LAN), and/or a wide area network (WAN).

This disclosure presents, among other things, various examples of operations that may be performed by an appropriately configured computing device. One example includes a computing device (e.g., a DS processing unit) that is configured to interact with a dispersed or distributed storage network (DSN) memory that includes a number of storage units (SUs). For example, when a computing device encounters write failures (but achieves at least a write threshold number of successes), the computing device can acknowledge a successful write to the requester. The computing device then saves the failed write operations in order to retry them at a later time. For example, when operations failed due to outage of SU, the computing device may resend the requests when the SU comes back online. In some examples, the computing device only has so much memory to use to store these failed requests, and it may drop them when this memory resource becomes full. For example, it may favor new failures over older ones and thus drop the failed requests which have been stored the longest (e.g., as they may have the lowest chance or require the most time before they can be successfully re-issued).

It is noted that terminologies as may be used herein such as bit stream, stream, signal sequence, etc. (or their equivalents) have been used interchangeably to describe digital information whose content corresponds to any of a number of desired types (e.g., data, video, speech, audio, etc. any of which may generally be referred to as ‘data’).

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may also be used herein, the terms “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A computing device comprising:
an interface configured to interface and communicate with a dispersed or distributed storage network (DSN);
memory that stores operational instructions; and
a processing module operably coupled to the interface and to the memory, wherein the processing module, when operable within the computing device based on the operational instructions, is configured to:
issue a plurality of write slice requests to a set of storage units (SUs) to store distributedly a set of encoded data slices (EDSs) associated with a data object, wherein the data object is segmented into a plurality of data segments, wherein a data segment of the plurality of data segments is dispersed error encoded in accordance with dispersed error encoding parameters to produce the set of EDSs, and wherein a write threshold number of EDSs provides for a successful transfer of the set of EDSs from a first at least one location in the DSN to a second at least one location in the DSN;
when at least a write threshold number of favorable write slice responses are received from at least the write threshold number of SUs of the set of SUs acknowledging storage of at least the write threshold number of EDSs of the set of EDSs, identify an EDS of the at least the write threshold number of EDSs without write confirmation and an SU associated with the EDS of the at least the write threshold number of EDSs without write confirmation;
store the EDS of the at least the write threshold number of EDSs without write confirmation in a slice cache memory of the computing device;
based on a determination to reissue a write slice request of the plurality of write slice requests associated with the EDS of the at least the write threshold number of EDSs without write confirmation, reissue the write slice request of the plurality of write slice requests to the SU associated with the EDS of the at least the write threshold number of EDSs without write confirmation; and
when a favorable write slice response is received from the SU associated with the EDS of the at least the write threshold number of EDSs without write confirmation in response to the write slice request of the plurality of write slice requests, delete the EDS of the at least the write threshold number of EDSs without write confirmation from the slice cache memory of the computing device.

2. The computing device of claim 1, wherein the processing module, when operable within the computing device based on the operational instructions, is further configured to:
when an unfavorable write slice response is received from the SU of the plurality of SUs associated with the EDS of the at least the write threshold number of EDSs without write confirmation in response to the write slice request of the plurality of write slice requests and based on another determination to reissue another write slice request of the plurality of write slice requests associated with the EDS of the at least the write threshold number of EDSs without write confirmation, reissue the another write slice request of the plurality of write slice requests to the SU of the plurality of SUs associated with the EDS of the at least the write threshold number of EDSs without write confirmation.

3. The computing device of claim 1, wherein the processing module, when operable within the computing device based on the operational instructions, is further configured to:
delete the EDS of the at least the write threshold number of EDSs without write confirmation from the slice cache memory of the computing device and store a new EDS of the at least the write threshold number of EDSs without write confirmation in the slice cache memory of the computing device when available storage space of the slice cache memory of the computing device is below a threshold.

4. The computing device of claim 1, wherein the processing module, when operable within the computing device based on the operational instructions, is further configured to:
determine whether to reissue the write slice request of the plurality of write slice requests associated with the EDS of the at least the write threshold number of EDSs without write confirmation based on at least one of receiving a SU availability indicator, interpreting a resend schedule, receiving an error message, receiving an access request response, receiving a resend request that request resending EDSs without write confirmation, or receiving a rebuilding request.

5. The computing device of claim 1, wherein:
a decode threshold number of EDSs are needed to recover the data segment;
a read threshold number of EDSs provides for reconstruction of the data segment;
the set of EDSs is of pillar width and includes a pillar number of EDSs;
each of the decode threshold, the read threshold, and the write threshold is less than the pillar number; and
the write threshold number is greater than or equal to the read threshold number that is greater than or equal to the decode threshold number.

6. The computing device of claim 1, wherein the computing device is located at a first premises that is remotely located from at least one SU of the plurality of SUs within the DSN.

7. The computing device of claim 1 further comprising:
a SU of the plurality of SUs within the DSN, a wireless smart phone, a laptop, a tablet, a personal computers (PC), a work station, or a video game device.

8. The computing device of claim 1, wherein the DSN includes at least one of a wireless communication system, a wire lined communication systems, a non-public intranet system, a public internet system, a local area network (LAN), or a wide area network (WAN).

9. A computing device comprising:
an interface configured to interface and communicate with a dispersed or distributed storage network (DSN);
memory that stores operational instructions; and
a processing module operably coupled to the interface and to the memory, wherein the processing module, when operable within the computing device based on the operational instructions, is configured to:
issue a plurality of write slice requests to a set of storage units (SUs) to store distributedly a set of encoded data slices (EDSs) associated with a data object, wherein the data object is segmented into a plurality of data segments, wherein a data segment of the plurality of data segments is dispersed error encoded in accordance with dispersed error encoding parameters to produce the set of EDSs, and wherein a write threshold number of EDSs provides for a successful transfer of the set of EDSs from a first at least one location in the DSN to a second at least one location in the DSN, wherein a decode threshold number of EDSs are needed to recover the data segment, wherein a read threshold number of EDSs provides for reconstruction of the data segment;
when at least a write threshold number of favorable write slice responses are received from at least the write threshold number of SUs of the set of SUs acknowledging storage of at least the write threshold number of EDSs of the set of EDSs, identify an EDS of the at least the write threshold number of EDSs without write confirmation and an SU associated with the EDS of the at least the write threshold number of EDSs without write confirmation;
store the EDS of the at least the write threshold number of EDSs without write confirmation in a slice cache memory of the computing device;
determine whether to reissue a write slice request of the plurality of write slice requests associated with the EDS of the at least the write threshold number of EDSs without write confirmation based on at least one of receiving a SU availability indicator, interpreting a resend schedule, receiving an error message, receiving an access request response, receiving a resend request that request resending EDSs without write confirmation, or receiving a rebuilding request.
based on a determination to reissue the write slice request of the plurality of write slice requests associated with the EDS of the at least the write threshold number of EDSs without write confirmation, reissue the write slice request of the plurality of write slice requests to the SU associated with the EDS of the at least the write threshold number of EDSs without write confirmation; and
when a favorable write slice response is received from the SU associated with the EDS of the at least the write threshold number of EDSs without write confirmation in response to the write slice request of the plurality of write slice requests, delete the EDS of the at least the write threshold number of EDSs without write confirmation from the slice cache memory of the computing device.

10. The computing device of claim 9, wherein the processing module, when operable within the computing device based on the operational instructions, is further configured to:
when an unfavorable write slice response is received from the SU of the plurality of SUs associated with the EDS of the at least the write threshold number of EDSs without write confirmation in response to the write slice request of the plurality of write slice requests and based on another determination to reissue another write slice request of the plurality of write slice requests associated with the EDS of the at least the write threshold number of EDSs without write confirmation, reissue the another write slice request of the plurality of write slice requests to the SU of the plurality of SUs associated with the EDS of the at least the write threshold number of EDSs without write confirmation.

11. The computing device of claim 9, wherein the processing module, when operable within the computing device based on the operational instructions, is further configured to:
delete the EDS of the at least the write threshold number of EDSs without write confirmation from the slice cache memory of the computing device and store a new EDS of the at least the write threshold number of EDSs without write confirmation in the slice cache memory of the computing device when available storage space of the slice cache memory of the computing device is below a threshold.

12. The computing device of claim 9, wherein the computing device is located at a first premises that is remotely located from at least one SU of the plurality of SUs within the DSN.

13. The computing device of claim 9, wherein the DSN includes at least one of a wireless communication system, a wire lined communication systems, a non-public intranet system, a public internet system, a local area network (LAN), or a wide area network (WAN).

14. A method for execution by a computing device, the method comprising:
issuing, via an interface of the computing device that is configured to interface and communicate with a dispersed or distributed storage network (DSN), a plurality of write slice requests to a set of storage units (SUs) to store distributedly a set of encoded data slices (EDSs) associated with a data object, wherein the data object is segmented into a plurality of data segments, wherein a data segment of the plurality of data segments is dispersed error encoded in accordance with dispersed error encoding parameters to produce the set of EDSs, and wherein a write threshold number of EDSs provides for a successful transfer of the set of EDSs from a first at least one location in the DSN to a second at least one location in the DSN;
when at least a write threshold number of favorable write slice responses are received via the interface from at least the write threshold number of SUs of the set of SUs acknowledging storage of at least the write threshold number of EDSs of the set of EDSs, identify an EDS of the at least the write threshold number of EDSs without write confirmation and an SU associated with the EDS of the at least the write threshold number of EDSs without write confirmation;
storing the EDS of the at least the write threshold number of EDSs without write confirmation in a slice cache memory of the computing device;
based on a determination to reissue a write slice request of the plurality of write slice requests associated with the EDS of the at least the write threshold number of EDSs without write confirmation, reissuing via the interface the write slice request of the plurality of write slice requests to the SU associated with the EDS of the at least the write threshold number of EDSs without write confirmation; and
when a favorable write slice response is received from the SU associated with the EDS of the at least the write threshold number of EDSs without write confirmation in response to the write slice request of the plurality of write slice requests, deleting the EDS of the at least the write threshold number of EDSs without write confirmation from the slice cache memory of the computing device.

15. The method of claim 14 further comprising:
when an unfavorable write slice response is received from the SU of the plurality of SUs associated with the EDS of the at least the write threshold number of EDSs without write confirmation in response to the write slice request of the plurality of write slice requests and based on another determination to reissue another write slice request of the plurality of write slice requests associated with the EDS of the at least the write threshold number of EDSs without write confirmation, reissuing via the interface the another write slice request of the plurality of write slice requests to the SU of the plurality of SUs associated with the EDS of the at least the write threshold number of EDSs without write confirmation.

16. The method of claim 14 further comprising:
deleting the EDS of the at least the write threshold number of EDSs without write confirmation from the slice cache memory of the computing device and store a new EDS of the at least the write threshold number of EDSs without write confirmation in the slice cache memory of the computing device when available storage space of the slice cache memory of the computing device is below a threshold.

17. The method of claim 14 further comprising:
determining whether to reissue the write slice request of the plurality of write slice requests associated with the EDS of the at least the write threshold number of EDSs without write confirmation based on at least one of receiving a SU availability indicator, interpreting a resend schedule, receiving an error message, receiving an access request response, receiving a resend request that request resending EDSs without write confirmation, or receiving a rebuilding request.

18. The method of claim 14, wherein:
a decode threshold number of EDSs are needed to recover the data segment;
a read threshold number of EDSs provides for reconstruction of the data segment;
the set of EDSs is of pillar width and includes a pillar number of EDSs;
each of the decode threshold, the read threshold, and the write threshold is less than the pillar number; and
the write threshold number is greater than or equal to the read threshold number that is greater than or equal to the decode threshold number.

19. The method of claim 14, wherein the computing device is located at a first premises that is remotely located from at least one SU of the plurality of SUs within the DSN.

20. The method of claim 14, wherein the DSN includes at least one of a wireless communication system, a wire lined communication systems, a non-public intranet system, a public internet system, a local area network (LAN), or a wide area network (WAN).
